(19) United States
(12) Patent Application Publication
(10) Pub. No.: US 2026/0066023 A1
(43) Pub. Date: Mar. 5, 2026

(54) HYBRID BUILT-IN SYSTEM TEST SWITCHING CIRCUITRY FOR EMBEDDED MEMORY TESTING

(71) Applicant: STMicroelectronics International N.V., Geneva (CH)

(72) Inventors: Praveen Kumar VERMA, Greater Noida (IN); Eric FAEHN, Saint Barthelemy De Sechilienne (FR); Cedric ESCALLIER, Seyssinet (FR); Kedar Janardan DHORI, Ghaziabad (IN); Harsh RAWAT, Faridabad (FR); Christophe LECOCQ, Varces (FR); Yagnesh Dineshbhai VADERIYA, Noida (IN); Amit SINGH, Noida (IN)

(21) Appl. No.: 19/293,485

(22) Filed: Aug. 7, 2025

Related U.S. Application Data
(60) Provisional application No. 63/688,009, filed on Aug. 28, 2024.

(51) Int. Cl. G11C 29/12

(52) U.S. Cl. CPC G11C 29/12005

(57) ABSTRACT

Various embodiments are directed to example system-on-chip integrated circuits configured to perform built-in self test operations on an embedded memory. An example system-on-chip integrated circuit includes dynamic BIST switching circuitry and an embedded memory. The dynamic BIST switching circuitry is configured to generate a dynamic BIST output based on a test state. The embedded memory is configured to receive the dynamic BIST output. The embedded memory includes fixed BIST switching circuitry configured to generate a fixed BIST output based on the test state. Wherein the fixed BIST switching circuitry is internal to the embedded memory, and the dynamic BIST switching circuitry is external to the embedded memory.

### CROSS-REFERENCE TO RELATED APPLICATIONS

This application claims the benefit of U.S. Provisional Patent Application No. 63/688,009, filed Aug. 28, 2024, the entire contents of which are hereby incorporated by reference in their entirety.

### TECHNOLOGICAL FIELD

Embodiments of the present disclosure relate generally to built-in self test (BIST) switching circuitry for embedded memory on a system-on-chip integrated circuit (SoC), and more particularly, to a hybrid implementation of the BIST switching circuitry on an SoC.

### BACKGROUND

System-on-chip integrated circuits (SoC) often utilize test procedures to ensure proper operation of the components of the electrical system. Memory is one such electrical component that requires a test procedure to ensure proper operation. A built-in self test (BIST) may be utilized to test the functionality of embedded memory on an SoC device. A BIST may utilize predefined test patterns to test the functionality of an embedded memory. For example, a BIST may write a pattern of ones and zeros to a block of embedded memory. Depending on the readout of the memory after writing the test pattern, the SoC may determine the operating status of the embedded memory.

Applicant has identified many technical challenges and difficulties associated with performing BIST operations on embedded memory. Through applied effort, ingenuity, and innovation, Applicant has solved problems related to executing BIST operations by developing solutions embodied in the present disclosure, which are described in detail below.

### BRIEF SUMMARY

Various embodiments are directed to example system-on-chip integrated circuits (SOC) configured to perform built-in self test (BIST) operations on an embedded memory. An example system-on-chip integrated circuit may comprise dynamic BIST switching circuitry and an embedded memory. The dynamic BIST switching circuitry is configured to generate a dynamic BIST output based on a test state. The embedded memory is configured to receive the dynamic BIST output. The embedded memory comprising fixed BIST switching circuitry configured to generate a fixed BIST output based on the test state. Wherein the fixed BIST switching circuitry is internal to the embedded memory, and the dynamic BIST switching circuitry is external to the embedded memory.

In some embodiments, the dynamic BIST output is a timing-critical memory signal.

In some embodiments, one or more pipeline registers are added to the dynamic BIST output between the dynamic BIST switching circuitry and the embedded memory.

In some embodiments, a dynamic setup time for the dynamic BIST switching circuitry is reduced relative to a fixed setup time for the fixed BIST switching circuitry.

In some embodiments, the fixed BIST output is not a timing-critical memory signal.

In some embodiments, one or more dynamic BIST transistors comprising the dynamic BIST switching circuitry are low voltage threshold (LVT) transistors.

In some embodiments, one or more fixed BIST transistors comprising the fixed BIST switching circuitry are high voltage threshold (HVT) transistors.

In some embodiments, the dynamic BIST switching circuitry comprises a multiplexer (mux).

In some embodiments, the embedded memory is static random-access memory (SRAM).

A second example system-on-chip integrated circuit is further provided. In some embodiments, the system-on-chip integrated circuit comprising dynamic BIST switching circuitry and embedded memory. The BIST switching circuitry is configured to generate one or more memory control signals based on a test state. The embedded memory is configured to receive the one or more memory control signals from the dynamic BIST switching circuitry. The embedded memory comprising fixed BIST switching configured to generate one or more data transmission signals based on the test state. Wherein the fixed BIST switching circuitry is internal to the embedded memory, and wherein the dynamic BIST switching circuitry is external to the embedded memory.

In some embodiments, the one or more memory control signals are timing-critical memory signals.

In some embodiments, the one or more memory control signals comprise at least an address signal, a chip select signal, or a write enable signal.

In some embodiments, the one or more data transmission signals comprise at least a data signal or mask signal.

In some embodiments, the one or more data transmission signals are based on a test data signal.

In some embodiments, the test data signal comprises a data clubbing number of bits defining a repeated test data pattern, and wherein the test data pattern is repeated for each data clubbing number of input/output (IO) blocks.

In some embodiments, the data clubbing number is 2, 4, 8, or 16.

A third example system-on-chip integrated circuit is also provided. In some embodiments, the system-on-chip integrated circuit includes dynamic BIST switching circuitry and embedded memory. The dynamic BIST switching circuitry configured to generate one or more data transmission signals based on a test state. The embedded memory configured to receive the one or more data transmission signals from the dynamic BIST switching circuitry. The embedded memory further comprising fixed BIST switching circuitry configured to generate one or more memory control signals based on the test state. Wherein the fixed BIST switching circuitry is internal to the embedded memory and wherein the dynamic BIST switching circuitry is external to the embedded memory.

In some embodiments, the one or more data transmission signals are timing-critical memory signals.

In some embodiments, the one or more data transmission signals comprise at least a data signal or mask signal.

In some embodiments, the one or more memory control signals comprise at least an address signal, a chip select signal, or a write enable signal.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1A-FIG. 1B depict a comparison between an example embedded memory comprising BIST switching circuitry positioned within the embedded memory and without the embedded memory.

FIG. 2 illustrates a block diagram of an example SoC in accordance with an example embodiment of the present disclosure.

FIG. 3 illustrates an example embodiment of hybrid BIST switching circuitry including dynamic BIST switching circuitry and fixed BIST switching circuitry in accordance with an example embodiment of the present disclosure.

FIG. 4 illustrates an example embodiment of hybrid BIST switching circuitry including dynamic BIST switching circuitry and fixed BIST switching circuitry in accordance with an example embodiment of the present disclosure.

FIG. 5 illustrates an example embedded memory including hybrid BIST switching circuitry utilizing data clubbing in accordance with an example embodiment of the present disclosure.

FIG. 6 illustrates an example block diagram of an example SoC comprising hybrid BIST switching circuitry utilizing a pipeline register in accordance with an example embodiment of the present disclosure.

FIG. 7 depicts an example block diagram of compute components of a controller in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

Various example embodiments address technical problems associated with performing BIST operations on an embedded memory of an SoC. As understood by those of skill in the field to which the present disclosure pertains, there are numerous example scenarios in which a user may desire to perform BIST operations on an embedded memory of an SoC.

For example, SoCs often utilize test procedures to ensure proper operation of the various electrical components of the SoC. Memory is one such electrical component that may require a test procedure to ensure proper operation. A BIST may be utilized to test the functionality of embedded memory on an SoC. A BIST may utilize predefined test patterns to test the functionality of an embedded memory. For example, a BIST may write a pattern of ones and zeros to a block of embedded memory. Depending on the readout of the memory after writing the test pattern, the SoC may determine the operating status of the embedded memory.

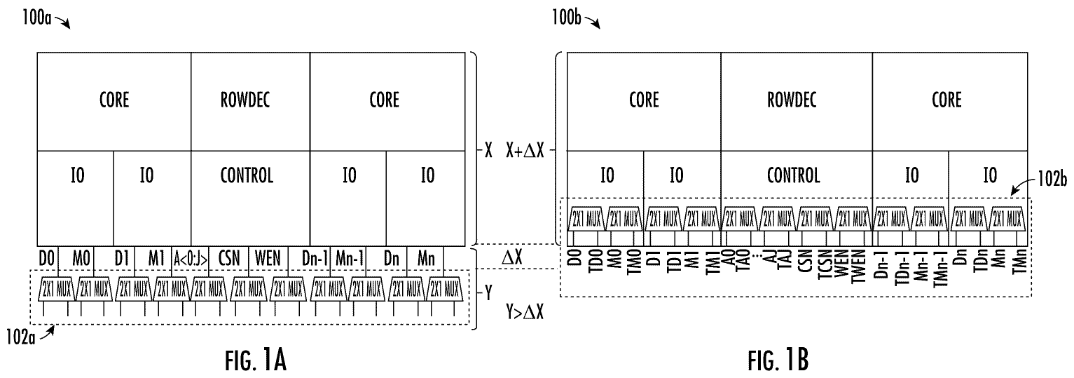

As depicted in FIG. 1A-FIG. 1B, execution of a BIST may require switching circuitry 102a, 102b (e.g., a plurality of 2×1 muxes) to toggle between standard operation memory signals and the BIST memory signals. In general, two different BIST implementations have been used, implementing the BIST switching circuitry 102a outside of the embedded memory 100a as shown in FIG. 1A, and implementing the BIST switching circuitry 102b within the embedded memory 100b as shown in FIG. 1B.

Each implementation of BIST switching circuitry 102a, 102b may provide advantages and disadvantages. For example, as depicted in FIG. 1A, the BIST switching circuitry 102a is positioned outside of the embedded memory 100a. Positioning the BIST switching circuitry 102a outside of the embedded memory 100a provides greater flexibility related to the design and operation of the BIST switching circuitry 102a. For example, an SoC design engineer may design and implement the BIST switching circuitry 102a in coordination with the SoC. In some embodiments, the embedded memory 100a may comprise timing-critical memory signals. For example, one or more memory control signals may limit the clock speed of the SoC. An SoC design engineer may choose to optimize the BIST switching circuitry 102a to reduce setup and/or hold times associated with the timing-critical memory signals to improve the overall performance of the embedded memory 100a and/or the SoC.

In addition to increased flexibility to optimize the memory interface signals, positioning the BIST switching circuitry 102a outside of the embedded memory 100a reduces the routing congestion at the embedded memory 100a, 100b. As depicted in FIG. 1A, only the outputs of the BIST switching circuitry 102a are routed to the embedded memory 100a. In contrast, as shown in FIG. 1B, a standard operation signal and a test signal are routed to the embedded memory 100b for every memory signal used during the BIST. By positioning the BIST switching circuitry 102a outside the embedded memory 100a, routing congestion and complexity are reduced at and around the embedded memory 100a.

However, there are also disadvantages to positioning the BIST switching circuitry 102a outside of the embedded memory 100a as shown in FIG. 1A. For example, positioning the BIST switching circuitry 102a outside of the embedded memory 100a may occupy more space. As shown in FIG. 1A, the additional space (Y) to accommodate the BIST switching circuitry 102a outside of the embedded memory 100a is greater than the additional space (ΔX) required by the embedded memory 100b to position the BIST switching circuitry 102b within the embedded memory 100b.

Further, the timing associated with an SoC including an embedded memory 100a with a BIST and associated BIST switching circuitry 102a may be affected by the configuration of the BIST switching circuitry 102a. Thus, in an instance in which the BIST switching circuitry 102a is optimized late in the design process, the overall timing of the SoC may be affected, making modifications to the overall design of the SoC necessary. In contrast, in an instance in which the BIST switching circuitry 102b is packaged within the embedded memory 100b, the timing characteristics of the embedded memory 100b, including the BIST switching circuitry 102b are established with the manufacture of the embedded memory 100b.

As depicted in FIG. 1B, positioning the BIST switching circuitry 102b within the embedded memory 100b utilizes less space (ΔX) compared to positioning the BIST switching circuitry 102a outside of the embedded memory 100a (X) as shown in FIG. 1A. However, positioning the BIST switching circuitry 102b within the embedded memory 100b may require additional memory signals to be routed to the embedded memory 100b. For example, a standard operation signal and a BIST signal are both routed to the embedded memory 100b for every memory signal used during operation of the BIST in an instance in which the BIST switching circuitry 102b is positioned within the embedded memory 100b. Routing additional signals to the embedded memory 100b may lead to additional congestion and complexity in routing in and around the embedded memory 100b.

The various example embodiments described herein provide hybrid BIST switching circuitry for an embedded memory on an SoC. The hybrid BIST switching circuitry includes dynamic BIST switching circuitry including the switching circuitry for one or more timing-critical memory signals of the embedded memory. The dynamic BIST switching circuitry is implemented at the SoC level, outside of the embedded memory. The hybrid BIST switching circuitry further includes fixed BIST switching circuitry including the switching circuitry for one or more low latency memory signals that are not typically time-critical memory signals of the embedded memory. The fixed BIST switching circuitry is implemented within the embedded memory. The hybrid BIST switching circuitry enables optimization of BIST switching circuitry based on area and timing constraints.

In addition, in some embodiments, data clubbing techniques may be utilized to further reduce the complexity and congestion associated with signal routing at or near the embedded memory. For example, in some embodiments, a repeated test data pattern may be written to the embedded memory during BIST operations. The test data pattern may enable the transmission of a test data signal and/or a test mask signal having a reduced number of bits. The test data pattern established by the reduced size test data signal may be repeated across sequential IO blocks of the embedded memory.

As a result of the herein described example embodiments and in some examples, the efficiency of an embedded memory may be greatly improved. For example, timing-critical signals of the embedded memory BIST may be optimized based on the parameters and constraints of the SoC. In addition, area utilized by the BIST switching circuitry and routing complexity in and around the embedded memory due to BIST switching circuitry, may be reduced.

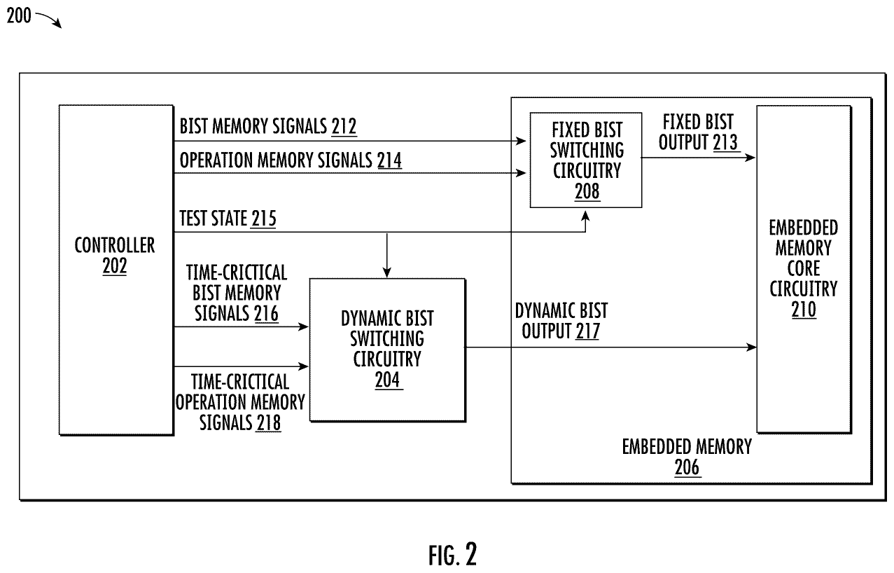

Referring now to FIG. 2, an example SoC 200 is provided. As depicted in FIG. 2, the example SoC 200 includes an embedded memory 206 comprising embedded memory core circuitry 210 and fixed BIST switching circuitry 208. The fixed BIST switching circuitry 208 configured to provide a fixed BIST output 213 to the embedded memory core circuitry 210. The example SoC 200 further includes a dynamic BIST switching circuitry 204 external to the embedded memory 206. The dynamic BIST switching circuitry 204 is configured to generate a dynamic BIST output 217 comprising one or more memory signals and transmit the dynamic BIST output 217 to the embedded memory 206. As further depicted in FIG. 2, the SoC 200 includes a controller 202 configured to generate BIST memory signals 212 and operation memory signals 214 for the fixed BIST switching circuitry 208; time-critical BIST memory signals 216 and time-critical operation memory signals 218 for the dynamic BIST switching circuitry 204; and a test state 215 signal.

As depicted in FIG. 2, an SoC 200 comprises any combination of hardware, software, and/or firmware comprising one or more integrated circuits and integrating most or all of the components of a computer or other electronic system. For example, an SoC 200 may include a central processing unit (CPU), microprocessor, or another controller (e.g., controller 202). An SoC 200 may further include one or more memory controllers configured to interface with embedded memory (e.g., embedded memory 206), external memory, flash memory, memory cache, and so on. An SoC 200 may further include various processing circuitry, such as radios, modems, input/output circuitry, graphics processing units, and so on. In some embodiments, the listed components may be implemented on a single substrate or microchip.

As further depicted in FIG. 2, the example SoC 200 includes an embedded memory 206. Embedded memory 206 comprises any hardware instantiated on the SoC 200 substrate and including associated software and/or firmware configured to store information. An embedded memory 206 may comprise non-volatile and/or volatile storage medium. Non-limiting non-volatile storage examples may include solid-state storage, read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Non-limiting, volatile storage examples may include random access memory (RAM), dynamic random-access memory (DRAM), static random-access memory (SRAM), and/or the like.

As further depicted in FIG. 2, the embedded memory 206 further includes embedded memory core circuitry 210. The embedded memory core circuitry 210 comprises the various electrical components necessary for the operation of and interface with the embedded memory 206. For example, embedded memory core circuitry 210 may include the memory core. The memory core comprises the various electrical components configured to store information and/or state. For example, the storage transistors or metal-oxide-semiconductor field-effect-transistors (MOSFETs).

The embedded memory core circuitry 210 may further include input-output (IO) circuitry. The IO circuitry comprises various electrical components configured to facilitate the transmission of read data from the memory core and/or the transmission of write data to the memory core.

The embedded memory core circuitry 210 further includes control circuitry. The control circuitry comprises various electrical components configured to control access to the memory core. For example, the control circuitry may enable read and/or writes to/from the memory core by way of read and write enable signals, chip select signals, and so on.

The embedded memory core circuitry 210 further includes decoder circuitry. The decoder circuitry comprises various electrical components configured to determine a memory location in the memory core based on a provided address.

As further depicted in FIG. 2, the embedded memory 206 includes fixed BIST switching circuitry 208. The fixed BIST switching circuitry 208 is contained within the embedded memory 206 and comprises the various circuitry including hardware and/or software for selecting between BIST memory signals 212 and operation memory signals 214 to generate a fixed BIST output 213 based on a test state 215. The Fixed BIST switching circuitry 208 may be a mix of combinational and/or sequential elements based upon requirements. The fixed BIST switching circuitry 208 is contained within the embedded memory 206, thus, the setup time, hold time, and other timing characteristics of the fixed BIST output 213 based on the BIST memory signals 212, operation memory signals 214, and test state 215 received at the input pins of the embedded memory 206 are fixed at the time of manufacture of the embedded memory 206.

In some embodiments, the fixed BIST switching circuitry 208 may be configured to select between the BIST memory signals 212 and the operation memory signals 214 based on the test state 215. The test state 215 comprises any signal configured to indicate the test condition of the SoC 200 in relation to the embedded memory 206. For example, a high logic signal (1) may indicate the SoC 200 is performing a BIST on the embedded memory 206. A low logic signal (0) may indicate the embedded memory 206 is under normal operation. In some embodiments, in an instance in which the test state 215 indicates the SoC 200 is performing a BIST on the embedded memory 206, the BIST memory signals 212 may be transmitted as the fixed BIST output 213. Further, in some embodiments, in an instance in which the test state 215 indicates the SoC 200 is in normal operation, the operation memory signals 214 may be transmitted as the fixed BIST output 213.

BIST memory signals 212 comprise any memory control or memory data signal transmitted to fixed BIST switching circuitry 208 for utilization during performance of a BIST. BIST memory signals 212 may include data transmission signals, such as data signals and mask signals. BIST memory signals 212 may also include memory control signals, such as address signals, chip select signals, write enable signals, and so on.

Similarly, operation memory signals 214 comprise any memory control or memory data signal transmitted to fixed BIST switching circuitry 208 for utilization during operation of the embedded memory.

Because the fixed BIST switching circuitry 208 is within the embedded memory 206, the timing of the BIST memory signals 212 and operation memory signals 214 through the fixed BIST switching circuitry 208 may not be modified once the embedded memory 206 is manufactured. Thus, in some embodiments, the BIST memory signals 212 and operation memory signals 214 may not include timing-critical memory signals.

Timing-critical memory signals are any memory signals on the critical path of the embedded memory 206. The critical path of the embedded memory 206 is the combinational path of the embedded memory having the maximum timing delay between registers and memory. The maximum clock rate of the embedded memory 206 and interfacing circuitry may be defined by the critical path.

In embodiments in which the fixed BIST switching circuitry 208 does not manage timing-critical memory signals, including the fixed BIST switching circuitry 208 within the embedded memory 206 enables area savings. For example, the fixed BIST switching circuitry 208 may comprise fixed BIST transistors. The type of transistor comprising the fixed BIST transistors may be selected based on performance requirements. For example, the transistor type may be selected to prioritize size over speed. For example, high voltage threshold (HVT) transistors may be utilized to reduce leakage power of the fixed BIST transistors comprising the fixed BIST switching circuitry 208.

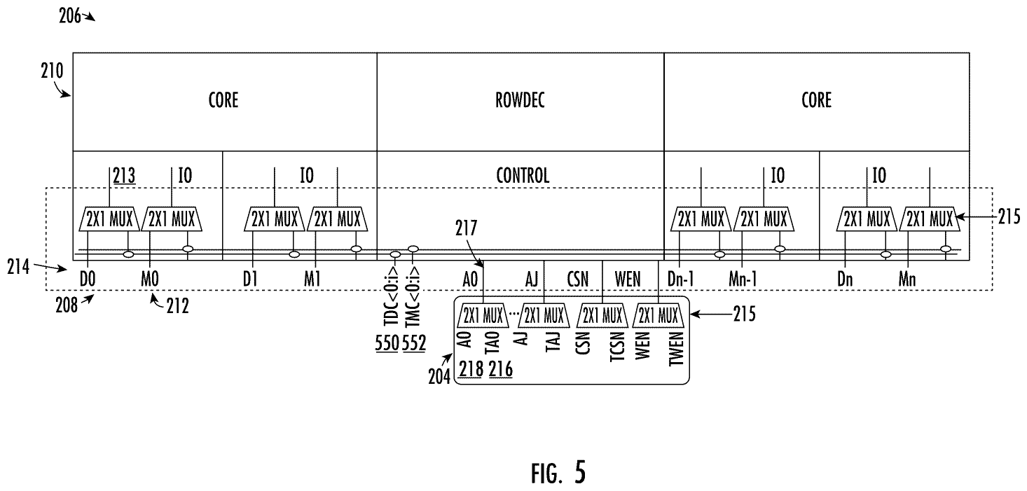

In some embodiments, BIST memory signals 212 may utilize data clubbing to reduce the size of the BIST memory signals 212 signal input into the embedded memory 206. Techniques related to data clubbing are discussed further in reference to FIG. 5.

As further depicted in FIG. 2, the example, SoC 200 includes dynamic BIST switching circuitry 204. The dynamic BIST switching circuitry 204 is external to the embedded memory 206 and comprises the various circuitry including hardware and/or software for selecting between time-critical BIST memory signals 216 and time-critical operation memory signals 218 to generate a dynamic BIST output 217 based on the test state 215. The dynamic BIST switching circuitry 204 is external to the embedded memory 206, and thus, the dynamic BIST switching circuitry may be modified based on the characteristics and requirements of the SoC 200, including the time-critical BIST memory signals 216, the time-critical operation memory signals 218, and the embedded memory 206.

For example, various components of the dynamic BIST switching circuitry 204 may be modified or adjusted to alter the setup time, hold time, and other timing characteristics of the dynamic BIST output 217. In this way, the time-critical BIST memory signals 216 and time-critical operation memory signals 218 may exhibit dynamic setup times and dynamic hold times. In some embodiments, the dynamic BIST switching circuitry 204 may comprise dynamic BIST transistors. The type of transistor comprising the dynamic BIST transistors may be selected based on performance requirements The technology and/or characteristics of the dynamic BIST transistors may be altered to change the timing characteristics of the time-critical BIST memory signals 216 and time-critical operation memory signals 218. For example, in some embodiments, the dynamic BIST transistors may comprise low-voltage threshold (LVT) transistors. LVT transistors may occupy more area however, the LVT transistors may also enable faster switching speeds. Such a prioritization of speed in the dynamic BIST transistors may decrease the setup and/or hold times of the dynamic BIST switching circuitry 204.

In some embodiments, the dynamic BIST switching circuitry 204 may be configured to select between the time-critical BIST memory signals 216 and the time-critical operation memory signals 218 based on the test state 215. In some embodiments, in an instance in which the test state 215 indicates the SoC 200 is performing BIST operations on the embedded memory 206, the time-critical BIST memory signals 216 may be transmitted as the dynamic BIST output 217. Further, in some embodiments, in an instance in which the test state 215 indicates the SoC 200 is in normal operation, the time-critical operation memory signals 218 may be transmitted as the dynamic BIST output 217.

As described herein, time-critical BIST memory signals 216 comprise any timing-critical memory signals transmitted to the dynamic BIST switching circuitry 204 for utilization during performance of a BIST on the embedded memory 206. Time-critical BIST memory signals 216 may include data transmission signals, such as data signals and mask signals. Time-critical BIST memory signals 216 may also include memory control signals, such as address signals, chip select signals, write enable signals, and so on.

Similarly, time-critical operation memory signals 218 comprise any timing-critical memory signals transmitted to the dynamic BIST switching circuitry 204 for utilization during standard operation of the embedded memory 206.

Because the dynamic BIST switching circuitry 204 is external to the embedded memory 206, the timing of the time-critical BIST memory signals 216 and time-critical operation memory signals 218 through the dynamic BIST switching circuitry 204 may optimized after the embedded memory 206 is manufactured. Thus, the dynamic BIST switching circuitry 204 provides flexibility in adjusting timing of some memory signals. In addition, selecting the dynamic BIST output 217 outside of the embedded memory 206 reduces the number of inputs necessary to support BIST operations at the embedded memory 206. Thus, the complexity of routing of signals in and around the embedded memory 206 may be reduced.

As further depicted in FIG. 2, the example SoC 200 includes a controller 202. A controller 202 comprises any processor, microcontroller, or other processing device configured to dictate the operations required to perform a BIST on an embedded memory. For example, the controller 202 may be configured to determine the test state 215 of the SoC 200. In some embodiments, the controller 202 may initiate a BIST at start-up, at a pre-determined interval, based on the state of the SoC 200, and/or as initiated by an external user or compute system. In an instance in which a BIST is initiated, the controller may toggle the test state 215 signal to indicate the start of a BIST procedure. In addition, the controller may be configured to provide BIST memory signals 212 and time-critical BIST memory signals 216 to test the embedded memory 206. For example, the controller 202 may configure the various memory signals to write a BIST pattern to one or more portions of the embedded memory 206 and subsequently read the written portion of the embedded memory 206. The controller 202 may further analyze the read memory data to determine the proper operation of the embedded memory 206.

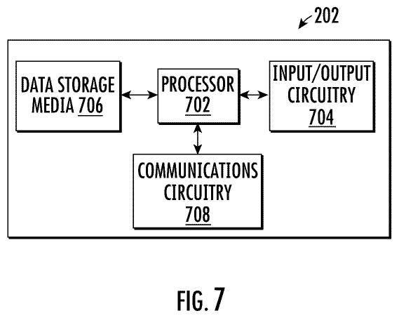

In some embodiments, the controller 202 may comprise a central processing unit (CPU). In such an embodiment, the controller 202 may be further configured to perform all necessary processing operations of the SoC 200. Such operations may include the configuration of operation memory signals 214 and time-critical operation memory signals 218 for utilization of the embedded memory 206 during operation. Although the operation memory signals 214 and time-critical operation memory signals 218 are derived from the controller 202 in FIG. 2, the operation memory signals 214 and time-critical operation memory signals 218 may be derived from any number of electronic sources on the SoC 200 or external to the SoC 200. An example configuration of a controller 202 is described in relation to FIG. 7.

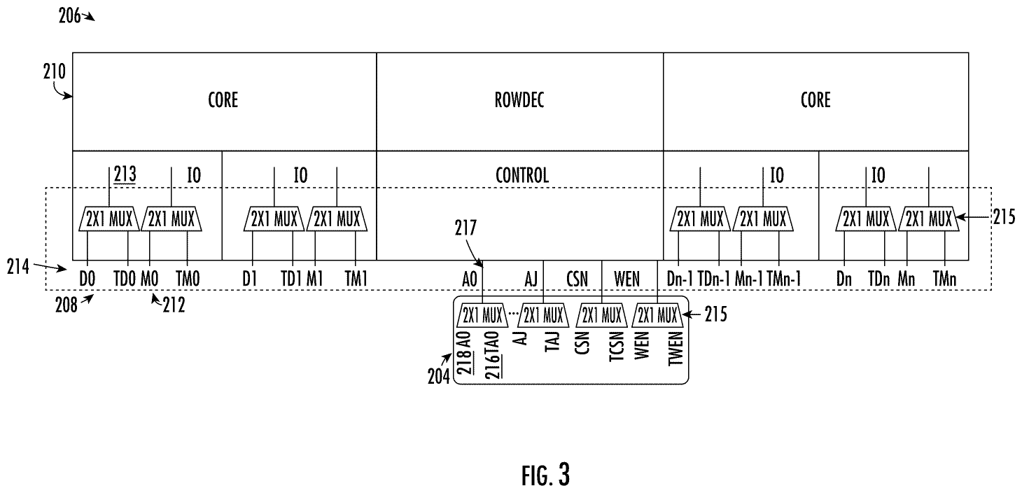

Referring now to FIG. 3, an example embodiment of an embedded memory 206 comprising hybrid BIST switching circuitry, including dynamic BIST switching circuitry 204 and fixed BIST switching circuitry 208 is provided. As depicted in FIG. 3, the embedded memory 206 includes embedded memory core circuitry 210 and fixed BIST switching circuitry 208. The fixed BIST switching circuitry 208 is configured to receive the data signals and mask signals as BIST memory signals 212 and operation memory signals 214 and generate a fixed BIST output based on the test state 215. As further depicted in FIG. 3, the dynamic BIST switching circuitry 204 is external to the embedded memory 206. The dynamic BIST switching circuitry 204 is configured to receive various memory control signals as time-critical BIST memory signals 216 and time-critical operation memory signals 218 and generate a dynamic BIST output 217 based on the test state 215.

As depicted in FIG. 3, the embedded memory 206 comprises embedded memory core circuitry 210. The example embedded memory core circuitry 210 includes control circuitry (CONTROL), core circuitry (CORE), decode circuitry (ROWDEC), and input/output circuitry (IO). The control circuitry is configured to receive various memory control signals, including address bits (A0-Aj), a chip select signal (CSN), and a write enable signal (WEN). In some embodiments, one or more of the memory control signals may be a timing-critical memory signal. For example, one or more of the memory control signals may comprise a portion of the critical path of the embedded memory 206. As such, the memory control signals are selected by the dynamic BIST switching circuitry 204 external to the embedded memory 206. By utilizing the dynamic BIST switching circuitry 204 to select the memory control signals, the selection of the memory control signals may be optimized based on timing constraints/requirements.

As depicted in FIG. 3, the dynamic BIST switching circuitry 204 comprise a plurality of muxes. Each mux is configured to receive a bit of the time-critical operation memory signal 218 (e.g., A0-Aj, CSN, WEN) and a corresponding bit of the time-critical BIST memory signal 216 (e.g., TA0-TAj, TCSN, TWEN). In an instance in which a BIST operation is performed as indicated by the test state 215 signal, the time-critical BIST memory signals 216 (e.g., TA0-TAj, TCSN, TWEN) are selected as the dynamic BIST output 217. Alternatively, in an instance in which the embedded memory 206 is operating normally, as indicated by the test state 215 signal, the time-critical operation memory signals 218 (e.g., A0-Aj, CSN, WEN) are selected as the dynamic BIST output 217. Thus, selection of the timing-critical memory control signals is performed outside of the embedded memory 206.

As further depicted in FIG. 3, the example embedded memory core circuitry 210 includes core circuitry (CORE). The core circuitry is configured to receive various data transmission signals, including data bits (D0-Dn) and mask bits (M0-Mn). The data bits and mask bits enable the corresponding data to be written to the target memory location. As depicted in FIG. 3, the data transmission signals are not timing-critical memory signals. Thus, the data transmission signals are selected by the fixed BIST switching circuitry 208 within the embedded memory 206. Utilizing fixed BIST switching circuitry 208 to control selection of the data transmission signals provides area savings and fixed timing characteristics for memory signals that are not timing-critical memory signals.

As depicted in FIG. 3, the fixed BIST switching circuitry 208 comprises a plurality of muxes. Each mux is configured to receive a bit of the operation memory signals 214 (e.g., D0-Dn, M0-Mn) and a corresponding bit of the BIST memory signals 212 (e.g., TD0-TDn, TM0-TMn). In an instance in which a BIST operation is performed as indicated by the test state 215 signal, the BIST memory signals (e.g., TD0-TDn, TM0-TMn) are selected as the fixed BIST output 213. Alternatively, in an instance in which the embedded memory 206 is operating normally, as indicated by the test state 215 signal, the operation memory signals 214 (e.g., D0-Dn, M0-Mn are selected as the fixed BIST output 213. Thus, selection of the data transmission signals is performed inside of the embedded memory 206.

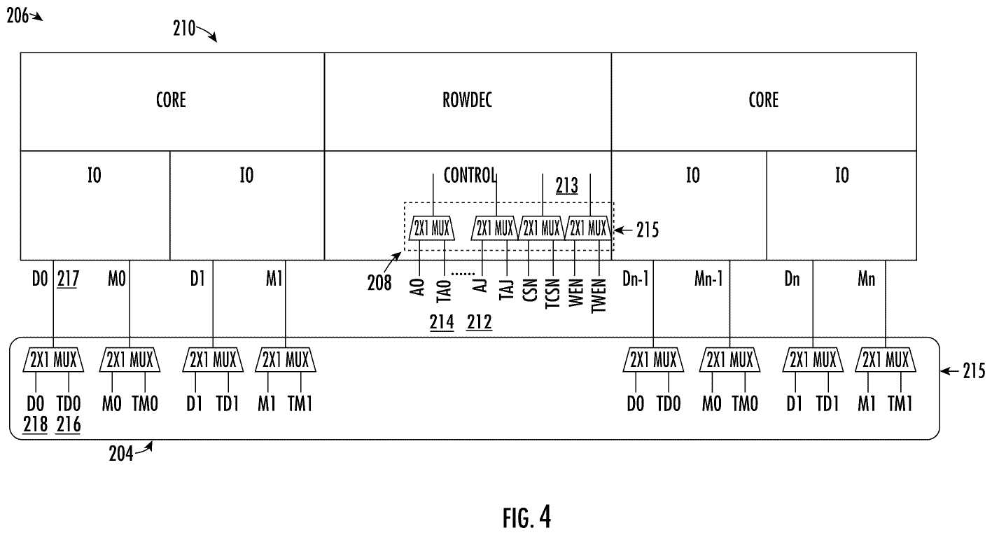

Referring now to FIG. 4, an example embodiment of an embedded memory 206 comprising hybrid BIST switching circuitry, including dynamic BIST switching circuitry 204, controlling data transmission signals, and fixed BIST switching circuitry 208, controlling memory control signals, is provided. As depicted in FIG. 4, the embedded memory 206 includes embedded memory core circuitry 210 and fixed BIST switching circuitry 208. The fixed BIST switching circuitry 208 is configured to receive various memory control signals as BIST memory signals 212 and operation memory signals 214 and generate a fixed BIST output 213 based on the test state 215. As further depicted in FIG. 4, the dynamic BIST switching circuitry 204 is external to the embedded memory 206. The dynamic BIST switching circuitry 204 is configured to receive various data transmission signals as time-critical BIST memory signals 216 and time-critical operation memory signals 218 and generate a dynamic BIST output 217 based on the test state 215.

As depicted in FIG. 4, the embedded memory 206 comprises embedded memory core circuitry 210. The example embedded memory core circuitry 210 includes control circuitry (CONTROL), core circuitry (CORE), decode circuitry (ROWDEC), and input/output circuitry (IO). The control circuitry is configured to receive various memory control signals, including address bits (A0-Aj), a chip select signal (CSN), and a write enable signal (WEN). In some embodiments, the memory control signals may not comprise timing-critical memory signals. As such, the timing characteristics of the embedded memory 206 may not benefit from increasing the speed of the switching circuitry associated with the memory control signals. In such an embodiment, the memory control signals may be selected by the fixed BIST switching circuitry 208, internal to the embedded memory 206. As depicted in FIG. 4, the fixed BIST switching circuitry 208 may include a plurality of muxes, each mux configured to receive a bit of the operation memory signals 214 (e.g., A0-Aj, CSN, WEN) and a corresponding bit of the BIST memory signals 212 (e.g., TA0-TAj, TCSN, TWEN). Selecting the memory control signals within the embedded memory 206 may enable area savings and provide established timing characteristics for the memory control signals of the embedded memory 206.

As further depicted in FIG. 4, the core circuitry is configured to receive various data transmission signals, including data bits (D0-Dn) and mask bits (M0-Mn). The data bits and mask bits enable the corresponding data to be written to the target memory location. As depicted in FIG. 4, in some embodiments, the data transmission signals may comprise timing-critical memory signals. For example, based on the size or shape of the embedded memory 206, the data transmission signals may be configured to travel a greater distance. Thus, as depicted in FIG. 4, the data transmission signals are selected by the dynamic BIST switching circuitry 204 outside the embedded memory 206. Utilizing dynamic BIST switching circuitry 204 to control selection of the timing-critical data transmission signals enables optimization of the dynamic BIST switching circuitry 204. For example, the dynamic BIST transistors comprising the dynamic BIST switching circuitry 204 may be selected to optimize speed. For example, LVT transistors may be utilized in the dynamic BIST switching circuitry 204.

As further depicted in FIG. 4, the dynamic BIST switching circuitry 204 comprises a plurality of muxes. Each mux is configured to receive a bit of the time-critical operation memory signal 218 (e.g., D0-Dn, M0-Mn) and a corresponding bit of the time-critical BIST memory signal 216 (e.g., TD0-TDn, TM0-TMn). In an instance in which a BIST operation is performed as indicated by the test state 215 signal, the time-critical BIST memory signals 216 (e.g., TD0-TDn, TM0-TMn) are selected as the dynamic BIST output 217. Alternatively, in an instance in which the embedded memory 206 is operating normally, as indicated by the test state 215 signal, the time-critical operation memory signals 218 (e.g., D0-Dn, M0-Mn) are selected as the dynamic BIST output 217. Thus, selection of the timing-critical memory control signals is performed outside of the embedded memory 206.

Referring now to FIG. 5, an example embodiment of an embedded memory 206 utilizing data clubbing is provided. As depicted in FIG. 5, the embedded memory 206 includes embedded memory core circuitry 210 and fixed BIST switching circuitry 208. The fixed BIST switching circuitry 208 is configured to receive the data signals and mask signals as operation memory signals 214. The fixed BIST switching circuitry 208 is further configured to receive test data signals 550 and test mask signals 552 as the BIST memory signals 212 during BIST performance. The embedded memory 206 is configured to generate a fixed BIST output 213 from the operation memory signals 214 and BIST memory signals 212 based on the test state 215. As further depicted in FIG. 5, the dynamic BIST switching circuitry 204 is external to the embedded memory 206. The dynamic BIST switching circuitry 204 is configured to receive various memory control signals as time-critical BIST memory signals 216 and time-critical operation memory signals 218 and generate a dynamic BIST output 217 based on the test state 215.

As depicted in FIG. 5, the routing complexity may be reduced at or near the embedded memory 206 by reducing the number of wires dedicated to the data signals and masking signals during operation of a BIST utilizing data clubbing. During BIST operation, certain repetitious data patterns may be written to all, or a portion of the memory locations in the embedded memory 206. For example, all memory locations may be written to 1, or all memory locations may be written to 0. In some embodiments, a repeated test pattern may be written to the memory locations. For example, sequential memory locations may be written with alternating 1s and 0s (e.g., 10101010 . . . ). In some embodiments, a test pattern may include writing two 1s, followed by two 0s (e.g., 110011001100 . . . ), four 1s followed by four 0s (e.g., 1111000011110000 . . . ), and so on. Data clubbing leverages repeated test data patterns to reduce the number of bits (e.g., data clubbing number of bits) required by the data signals and mask signals during BIST operation.

For example, an alternating test pattern of 1s and 0s may be expressed with a test data signal 550 of just two bits (‘01’). The test data signal 550 may be utilized to write sequential data blocks with the test data pattern, and then repeated for the next set of sequential data blocks, and so on. Thus, during BIST operation, the entire memory can be written based on a reduced number of data clubbing bits. Similarly, the mask signal 552 may be reduced based on a test pattern.

In some embodiments, the data clubbing number of bits comprising the test data signal 550 may be 2 bits, 4 bits, 8 bits, or 16 bits. However, the data clubbing number of bits may be any number up to the size of the embedded memory 206.

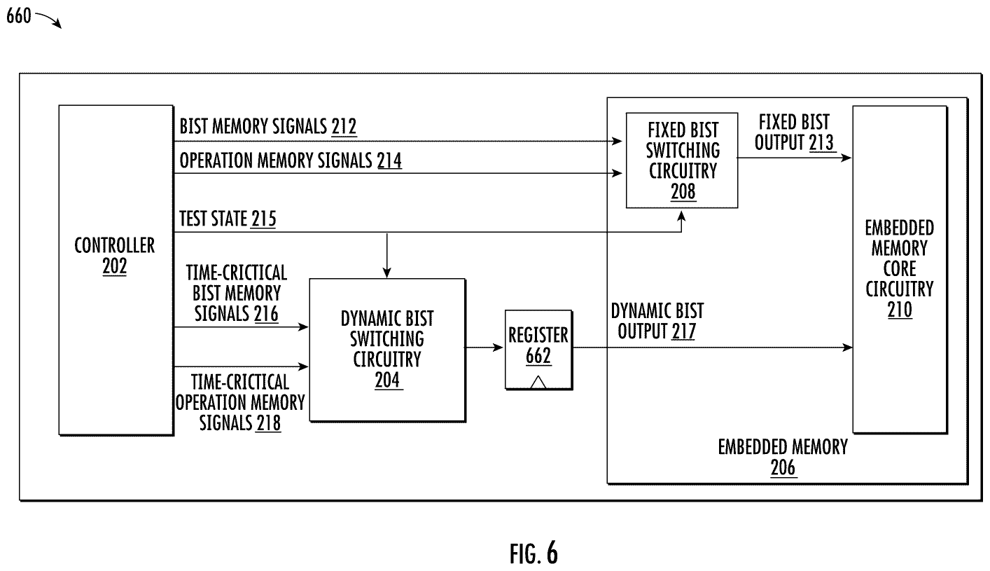

Referring now to FIG. 6, an example SoC 660 comprising a pipeline register 662 is provided. As depicted in FIG. 6, the example SoC 660 includes an embedded memory 206 comprising embedded memory core circuitry 210 and fixed BIST switching circuitry 208. The fixed BIST switching circuitry 208 configured to provide a fixed BIST output 213 to the embedded memory core circuitry 210. The example SoC 660 further includes dynamic BIST switching circuitry 204 external to the embedded memory 206. The dynamic BIST switching circuitry 204 is configured to generate a dynamic BIST output 217 comprising one or more memory signals and transmit the dynamic BIST output 217 to the embedded memory 206. As further depicted in FIG. 6, the dynamic BIST output 217 passes through a pipeline register 662 positioned between the dynamic BIST switching circuitry 204 and the embedded memory 206. The SoC 200 further includes a controller 202 configured to generate BIST memory signals 212 and operation memory signals 214 for the fixed BIST switching circuitry 208; time-critical BIST memory signals 216 and time-critical operation memory signals 218 for the dynamic BIST switching circuitry 204; and a test state 215 signal.

As depicted in FIG. 6, the example SoC 660 includes a pipeline register 662 positioned between the dynamic BIST switching circuitry 204 and the embedded memory 206. A pipeline register 662 is any memory or information storage device configured to store one or more data elements. A pipeline register 662 may comprise a flip-flop, such as a D flip-flop. A pipeline register 662 may be synchronized with a clock signal. One or more pipeline registers may provide further flexibility when determining the timing characteristics of the time-critical BIST memory signals 216 and the time-critical operation memory signals 218. For example, a pipeline register 662 may be positioned between the dynamic BIST switching circuitry 204 and the embedded memory 206 to reduce the time between data storage points on a data path. By reducing the time between data storage points, the clock speed may be increased for the embedded memory 206. A plurality of pipeline registers 662 may be positioned before, within, or after the dynamic BIST switching circuitry 204 based on the timing characteristics of the SoC 660 and embedded memory 206.

Referring now to FIG. 7, an example controller 202 in accordance with at least some example embodiments of the present disclosure is illustrated. The controller 202 includes processor 702, input/output circuitry 704, data storage media 706, and communications circuitry 708. In some embodiments, the controller 202 is configured, using one or more of the sets of circuitry 702, 704, 706, and/or 708, to execute and perform the operations described herein.

Although components are described with respect to functional limitations, it should be understood that the particular implementations necessarily include the use of particular computing hardware. It should also be understood that in some embodiments certain of the components described herein include similar or common hardware. For example, two sets of circuitry may both leverage use of the same processor(s), network interface(s), storage medium(s), and/or the like, to perform their associated functions, such that duplicate hardware is not required for each set of circuitry. The user of the term “circuitry” as used herein with respect to components of the apparatuses described herein should therefore be understood to include particular hardware configured to perform the functions associated with the particular circuitry as described herein.

Particularly, the term “circuitry” should be understood broadly to include hardware and, in some embodiments, software for configuring the hardware. For example, in some embodiments, “circuitry” includes processing circuitry, storage media, network interfaces, input/output devices, and/or the like. Alternatively, or additionally, in some embodiments, other elements of the controller 202 provide or supplement the functionality of other particular sets of circuitry. For example, the processor 702 in some embodiments provides processing functionality to any of the sets of circuitry, the data storage media 706 provides storage functionality to any of the sets of circuitry, the communications circuitry 708 provides network interface functionality to any of the sets of circuitry, and/or the like.

In some embodiments, the processor 702 (and/or co-processor or any other processing circuitry assisting or otherwise associated with the processor) is/are in communication with the data storage media 706 via a bus for passing information among components of the controller 202. In some embodiments, for example, the data storage media 706 is non-transitory and may include, for example, one or more volatile and/or non-volatile memories. In other words, for example, the data storage media 706 in some embodiments includes or embodies an electronic storage device (e.g., a computer readable storage medium). In some embodiments, the data storage media 706 is configured to store information, data, content, applications, instructions, or the like, for enabling the controller 202 to carry out various functions in accordance with example embodiments of the present disclosure.

The processor 702 may be embodied in a number of different ways. For example, in some example embodiments, the processor 702 includes one or more processing devices configured to perform independently. Additionally, or alternatively, in some embodiments, the processor 702 includes one or more processor(s) configured in tandem via a bus to enable independent execution of instructions, pipelining, and/or multithreading. The use of the terms “processor” and “processing circuitry” should be understood to include a single core processor, a multi-core processor, multiple processors internal to the controller 202, and/or one or more remote or “cloud” processor(s) external to the controller 202.

In an example embodiment, the processor 702 is configured to execute instructions stored in the data storage media 706 or otherwise accessible to the processor. Alternatively, or additionally, the processor 702 in some embodiments is configured to execute hard-coded functionality. As such, whether configured by hardware or software methods, or by a combination thereof, the processor 702 represents an entity (e.g., physically embodied in circuitry) capable of performing operations according to an embodiment of the present disclosure while configured accordingly. Alternatively, or additionally, as another example in some example embodiments, when the processor 702 is embodied as an executor of software instructions, the instructions specifically configure the processor 702 to perform the algorithms embodied in the specific operations described herein when such instructions are executed.

In some embodiments, the controller 202 includes input/output circuitry 704 that provides output to the user and, in some embodiments, to receive an indication of a user input. In some embodiments, the input/output circuitry 704 is in communication with the processor 702 to provide such functionality. The input/output circuitry 704 may comprise one or more user interface(s) (e.g., user interface) and in some embodiments includes a display that comprises the interface(s) rendered as a web user interface, an application user interface, a user device, a backend system, or the like. The processor 702 and/or input/output circuitry 704 comprising the processor may be configured to control one or more functions of one or more user interface elements through computer program instructions (e.g., software and/or firmware) stored on a memory accessible to the processor (e.g., data storage media 706, and/or the like). In some embodiments, the input/output circuitry 704 includes or utilizes a user-facing application to provide input/output functionality to a client device and/or other display associated with a user.

In some embodiments, the controller 202 includes communications circuitry 708. The communications circuitry 708 includes any means such as a device or circuitry embodied in either hardware or a combination of hardware and software that is configured to receive and/or transmit data from/to a network and/or any other device, circuitry, or module in communication with the controller 202. In this regard, the communications circuitry 708 includes, for example in some embodiments, a network interface for enabling communications with a wired or wireless communications network. Additionally, or alternatively in some embodiments, the communications circuitry 708 includes one or more network interface card(s), antenna(s), bus(es), switch(es), router(s), modem(s), and supporting hardware, firmware, and/or software, or any other device suitable for enabling communications via one or more communications network(s). Additionally, or alternatively, the communications circuitry 708 includes circuitry for interacting with the antenna(s) and/or other hardware or software to cause transmission of signals via the antenna(s) or to handle receipt of signals received via the antenna(s). In some embodiments, the communications circuitry 708 enables transmission to and/or receipt of data from a client device in communication with the controller 202.

Additionally, or alternatively, in some embodiments, one or more of the sets of circuitry 702-708 are combinable. Additionally, or alternatively, in some embodiments, one or more of the sets of circuitry perform some or all of the functionality described associated with another component. For example, in some embodiments, one or more sets of circuitry 702-708 are combined into a single module embodied in hardware, software, firmware, and/or a combination thereof.

While this detailed description has set forth some embodiments of the present invention, the appended claims cover other embodiments of the present invention which differ from the described embodiments according to various modifications and improvements. For example, one skilled in the art may recognize that such principles may be applied to any electronic device that is configured to perform a built-in self test on a memory device.

Within the appended claims, unless the specific term “means for” or “step for” is used within a given claim, it is not intended that the claim be interpreted under 35 U.S.C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A system-on-chip integrated circuit, comprising:
dynamic built-in system test (BIST) switching circuitry configured to generate a dynamic BIST output based on a test state; and
embedded memory configured to receive the dynamic BIST output, the embedded memory further comprising:
fixed BIST switching circuitry configured to generate a fixed BIST output based on the test state,
wherein the fixed BIST switching circuitry is internal to the embedded memory;
wherein the dynamic BIST switching circuitry is external to the embedded memory.

2. The system-on-chip integrated circuit of claim 1, wherein the dynamic BIST output is a timing-critical memory signal.

3. The system-on-chip integrated circuit of claim 2, wherein one or more pipeline registers are added to the dynamic BIST output between the dynamic BIST switching circuitry and the embedded memory.

4. The system-on-chip integrated circuit of claim 2, wherein a dynamic setup time for the dynamic BIST switching circuitry is reduced relative to a fixed setup time for the fixed BIST switching circuitry.

5. The system-on-chip integrated circuit of claim 2, wherein the fixed BIST output is not a timing-critical memory signal.

6. The system-on-chip integrated circuit of claim 1, wherein one or more dynamic BIST transistors comprising the dynamic BIST switching circuitry are low voltage threshold (LVT) transistors.

7. The system-on-chip integrated circuit of claim 1, wherein one or more fixed BIST transistors comprising the fixed BIST switching circuitry are high voltage threshold (HVT) transistors.

8. The system-on-chip integrated circuit of claim 1, wherein the dynamic BIST switching circuitry comprises a multiplexer (mux).

9. The system-on-chip integrated circuit of claim 1, wherein the embedded memory is static random-access memory (SRAM).

10. A system-on-chip integrated circuit, comprising:
dynamic built-in system test (BIST) switching circuitry configured to generate one or more memory control signals based on a test state; and
embedded memory configured to receive the one or more memory control signals from the dynamic BIST switching circuitry, the embedded memory further comprising:
fixed BIST switching circuitry configured to generate one or more data transmission signals based on the test state,
wherein the fixed BIST switching circuitry is internal to the embedded memory;
wherein the dynamic BIST switching circuitry is external to the embedded memory.

11. The system-on-chip integrated circuit of claim 10, wherein the one or more memory control signals are timing-critical memory signals.

12. The system-on-chip integrated circuit of claim 10, wherein the one or more memory control signals comprise at least an address signal, a chip select signal, or a write enable signal.

13. The system-on-chip integrated circuit of claim 10, wherein the one or more data transmission signals comprise at least a data signal or mask signal.

14. The system-on-chip integrated circuit of claim 10, wherein the one or more data transmission signals are based on a test data signal.

15. The system-on-chip integrated circuit of claim 14, wherein the test data signal comprises a data clubbing number of bits defining a repeated test data pattern, and wherein the test data pattern is repeated for each data clubbing number of input/output (IO) blocks.

16. The system-on-chip integrated circuit of claim 15, wherein the data clubbing number is 2, 4, 8, or 16.

17. A system-on-chip integrated circuit, comprising:
dynamic built-in system test (BIST) switching circuitry configured to generate one or more data transmission signals based on a test state; and
embedded memory configured to receive the one or more data transmission signals from the dynamic BIST switching circuitry, the embedded memory further comprising:
fixed BIST switching circuitry configured to generate one or more memory control signals based on the test state,
wherein the fixed BIST switching circuitry is internal to the embedded memory;
wherein the dynamic BIST switching circuitry is external to the embedded memory.

18. The system-on-chip integrated circuit of claim 17, wherein the one or more data transmission signals are timing-critical memory signals.

19. The system-on-chip integrated circuit of claim 17, wherein the one or more data transmission signals comprise at least a data signal or mask signal.

20. The system-on-chip integrated circuit of claim 17, wherein the one or more memory control signals comprise at least an address signal, a chip select signal, or a write enable signal.
